(19) United States
(12) Patent Application Publication
(10) Pub. No.: US 2024/0381586 A1
(43) Pub. Date: Nov. 14, 2024

(54) SYSTEMS AND METHODS FOR LEAK AND EVAPORATION DETECTION IN LIQUID-COOLED INFORMATION HANDLING SYSTEMS

(71) Applicant: Dell Products L.P., Round Rock, TX (US)

(72) Inventors: Weidong ZUO, Shrewsbury, MA (US); Dominick LOVICOTT, Jarrell, TX (US); Shih-Huai CHO, New Taipei City (TW)

(73) Assignee: Dell Products L.P., Round Rock, TX (US)

(21) Appl. No.: 18/315,847

(22) Filed: May 11, 2023

(51) Int. Cl. H05K 7/20; G01M 3/18

(52) U.S. Cl. CPC H05K 7/20781; G01M 3/188; H05K 7/20272; H05K 7/20736; H05K 7/20836

(57) ABSTRACT

An information handling system may include an information handling resource and a liquid cooling system for providing cooling of the information handling resource. The liquid cooling system may include a pump configured to drive flow of a liquid coolant through the liquid cooling system, a pump speed sensor configured to generate a pump speed signal indicative of a speed associated with the pump, and a processing device configured to receive the pump speed signal, determine whether the speed exceeds a threshold pump speed, and if the speed exceeds the threshold pump speed, take one or more remedial actions.

### TECHNICAL FIELD

The present disclosure relates in general to information handling systems, and more particularly to leak and evaporation detection in liquid-cooled information handling systems.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAN) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. Traditional approaches to cooling components may include a “passive” cooling system that serves to reject heat of a component to air driven by one or more system-level air movers (e.g., fans) for cooling multiple components of an information handling system in addition to the peripheral component. Another traditional approach may include an “active” cooling system that uses liquid cooling, in which a heat-exchanging cold plate is thermally coupled to the component, and a chilled fluid is passed through conduits internal to the cold plate to remove heat from the component. Yet another approach is liquid-assisted air cooling, in which heat is transferred from a heat-generating device to liquid within a loop comprising a radiator, and an air mover may drive air flow proximate to the radiator to transfer heat from the radiator to the air.

However, one disadvantage to using liquid or liquid-assisted cooling is that components of the liquid cooling system (e.g., fluid fittings, fluid joints, hoses or other fluidic conduits, pumps, cold plates, etc.) may develop leaks over time due to vibration, thermal cycles, or aging. Liquid leaks within an information handling system may cause corrosion to components of the information handling system, damage to electrical or electronic circuitry of the information handling system, and reduce ability of the liquid-cooled system to provide adequate thermal control. Many approaches have been used to detect leaks in a liquid-cooled system and provide a remedial action (e.g., shutdown, alert, etc.), wherein such approaches often operate by detecting the presence of actual coolant that has leaked (e.g., by detecting the presence of unexpected moisture external to a liquid coolant loop).

In addition to leaks, liquid coolant may also be depleted by evaporation through softer materials (e.g., pumps, fluidic conduits, etc.) of the liquid coolant loop. Such evaporation may reduce ability of the liquid-cooled system to provide adequate thermal control. However, existing approaches used to detect for the presence of leaks are often unable to detect for liquid coolant that has been depleted via evaporation.

### SUMMARY

In accordance with the teachings of the present disclosure, the disadvantages and problems associated with detecting leaks of fluid from liquid cooling systems may be substantially reduced or eliminated.

In accordance with embodiments of the present disclosure, an information handling system may include an information handling resource, a liquid cooling system for providing cooling of the information handling resource. The liquid cooling system may include a pump configured to drive flow of a liquid coolant through the liquid cooling system, a pump speed sensor configured to generate a pump speed signal indicative of a speed associated with the pump, and a processing device configured to receive the pump speed signal, determine whether the speed exceeds a threshold pump speed, and if the speed exceeds the threshold pump speed, take one or more remedial actions.

In accordance with these and other embodiments of the present disclosure, a method may include, in an information handling system having an information handling resource and a liquid cooling system for providing cooling of the information handling resource, receiving a pump speed signal indicative of speed associated with a pump configured to drive flow of a liquid coolant through the liquid cooling system, determining whether the speed exceeds a threshold pump speed, and if the speed exceeds the threshold pump speed, taking one or more remedial actions.

In accordance with these and other embodiments of the present disclosure, a system for detecting depletion of a liquid from a liquid system may include a pump speed sensor configured to generate a pump speed signal indicative of a speed associated with a pump for driving flow of liquid through the liquid system and a processing device configured to receive the pump speed signal, determine whether the speed exceeds a threshold pump speed, and if the speed exceeds the threshold pump speed, take one or more remedial actions.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIG. 2 illustrates a graph of an example relationship between pump speed as a function of a volume of liquid coolant depleted from a liquid cooling system, in accordance with embodiments of the present disclosure; and

FIG. 3 illustrates a flow chart of an example method for leak and evaporation detection in a liquid-cooled information handling system, in accordance with embodiments of the present disclosure.

### DETAILED DESCRIPTION

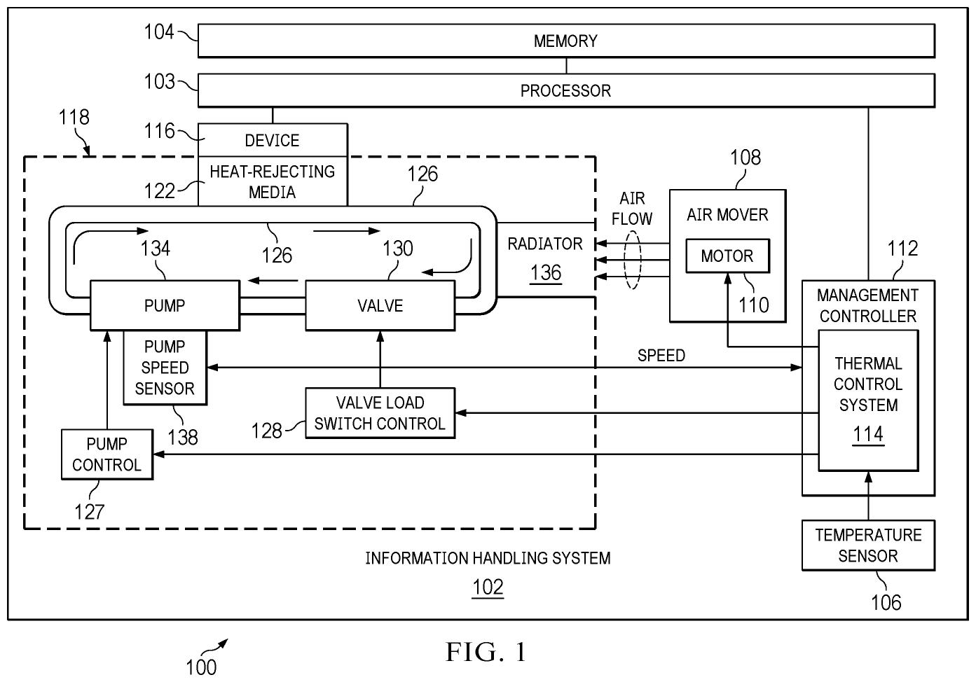

Preferred embodiments and their advantages are best understood by reference to FIGS. 1 through 3, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RA), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may include a chassis 100 housing a processor 103, a memory 104, a temperature sensor 106, an air mover 108, a management controller 112, a device 116, and a liquid cooling system 118.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAN), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal communicated from thermal control system 114 of management controller 112. In operation, air mover 108 may cool information handling resources of information handling system 102 by drawing cool air into an enclosure housing the information handling resources from outside the chassis, expel warm air from inside the enclosure to the outside of such enclosure, and/or move air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 106), and based on such signals, calculate an air mover driving signal to maintain an appropriate level of cooling, increase cooling, or decrease cooling, as appropriate, and communicate such air mover driving signal to air mover 108. In these and other embodiments, thermal control system 114 may be configured to receive information from other information handling resources and calculate the air mover driving signal based on such received information in addition to temperature information. For example, as described in greater detail below, thermal control system 114 may receive configuration data from device 116 and/or other information handling resources of information handling system 102, which may include thermal requirement information of one or more information handling resources. In addition to temperature information collected from sensors within information handling system 102, thermal control system 114 may also calculate the air mover driving signal based on such information received from information handling resources.

Temperature sensor 106 may be any system, device, or apparatus (e.g., a thermometer, thermistor, etc.) configured to communicate a signal to processor 103 or another controller indicative of a temperature within information handling system 102. In many embodiments, information handling system 102 may comprise a plurality of temperature sensors 106, wherein each temperature sensor 106 detects a temperature of a particular component and/or location within information handling system 102.

Device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

As shown in FIG. 1, liquid cooling system 118 may include heat-rejecting media 122, pump 134, radiator 136, valve 130, fluidic conduits 126, pump control subsystem 127, valve load switch control subsystem 128, and pump speed sensor 138.

Pump control subsystem 127 may include any system, device, or apparatus configured to control operation of pump 134. For example, such control may include controlling a pressure applied to coolant fluid in fluidic conduits 126 for moving such fluid through fluidic conduits 126. Valve load switch control subsystem 128 may include any system, device, or apparatus configured to control operation of valve 130. For example, such control may include opening or closing valve 130, controlling an aperture of valve 130, etc.

Pump 134 may be fluidically coupled to one or more fluidic conduits 126 and may comprise any mechanical or electro-mechanical system, apparatus, or device operable to produce a flow of fluid (e.g., fluid in one or more conduits 126). For example, pump 134 may produce fluid flow by applying a pressure to fluid in fluidic conduits 126. As described above, operation of pump 134 may be controlled by pump control subsystem 127 which may control electro-mechanical components of pump 134 in order to produce a desired rate of coolant flow.

Pump speed sensor 138 may be integral to or located proximate to pump 134, and may include any system, device, or apparatus configured to sense a speed (e.g., a rotational speed) of pump 134 and generate a speed signal SPEED indicative of such speed. For example, in some embodiments, pump speed sensor 138 may include a Hall sensor or similar sensor. As described in greater detail below, management controller 112 may use such measurement of pump speed to detect for leaks or evaporation of liquid coolant.

Radiator 136 may include any device, system or apparatus configured to transfer thermal energy from one medium (e.g., fluid within a fluidic conduit 126) to another (e.g., air external to chassis 100) for the purpose of cooling and heating. In some embodiments, radiator 136 may include fluidic channels and/or conduits in at least a portion of radiator 136. Such fluidic channels and/or conduits may be fluidically coupled to one or more of fluidic conduits 126 and pump 134.

Valve 130 may include any device, system or apparatus that regulates, directs, and/or controls the flow of a fluid (e.g., a coolant liquid in fluidic conduits 126) by opening, closing, or partially obstructing one or more passageways. When valve 130 is open, coolant liquid may flow in a direction from higher pressure to lower pressure. As described above, the operation of valve 130 (e.g., opening and closing, size of an aperture of valve 130) may be controlled by valve load switch control subsystem 128.

In operation, pump 134 may induce a flow of liquid (e.g., water, ethylene glycol, propylene glycol, or other coolant) through various fluidic conduits 126 of information handling system 102, valve 130 and/or radiator 136. As fluid passes by heat-rejecting media 122 in a fluidic conduit 126 proximate to device 116, heat may be transferred from device 116 to heat-rejecting media 122 and from heat-rejecting media 122 to the liquid coolant in fluidic conduit 126. As such heated coolant flows by radiator 136, heat from the coolant may be transferred from the coolant to air ambient to chassis 100 (including air flow driven from air mover 108 proximate to radiator 136), thus cooling the fluid.

Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include a solid thermally coupled to the information handling resource (e.g., heatpipe, heat spreader, heatsink, finstack, etc.) such that heat generated by the information handling resource is transferred from the information handling resource.

Accordingly, liquid cooling system 118 and its various components may be configured to provide active liquid cooling of device 116 and/or, in connection with air mover 108, may be configured to provide liquid-assisted air cooling of device 116.

In addition to processor 103, memory 104, temperature sensor 106, air mover 108, management controller 112, device 116, and liquid cooling system 118, information handling system 102 may include one or more other information handling resources. In addition, for the sake of clarity and exposition of the present disclosure, FIG. 1 depicts only one air mover 108 and one device 116. In embodiments of the present disclosure, information handling system 102 may include any number of air movers 108 and devices 116. Furthermore, for the sake of clarity and exposition of the present disclosure, FIG. 1 depicts device 116 including a liquid cooling system 118 for cooling of device 116. However, in some embodiments, approaches similar or identical to those used to cool device 116 as described herein may be employed to provide cooling of processor 103, memory 104, management controller 112, and/or any other information handling resource of information handling system 102.

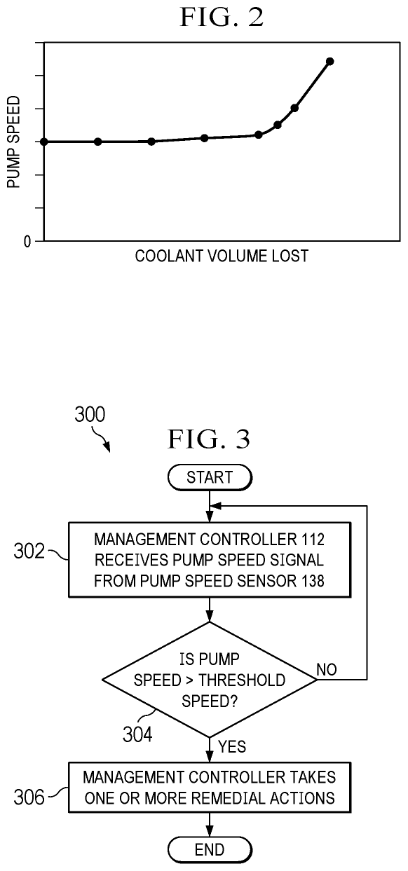

FIG. 2 illustrates a graph of an example relationship between pump speed of pump 134 as a function of a volume of liquid coolant depleted from liquid cooling system 118, in accordance with embodiments of the present disclosure. As shown in FIG. 2, pump speed of pump 134 as a function of time may remain substantially unchanged as a function of the depleted volume of coolant when the depleted volume of coolant is below a particular threshold. However, when the depleted volume of coolant exceeds the particular threshold, pump speed of pump 134 may increase significantly as the depleted volume of coolant increases. Accordingly, by monitoring speed signal SPEED indicative of the pump speed, management controller 112 may detect changes in pump speed that may be indicative of significant depletion of coolant volume through leaks and/or evaporation, and take one or more remedial actions responsive to determining that significant depletion of coolant volume has occurred.

FIG. 3 illustrates a flow chart of an example method 300 for leak and evaporation detection in a liquid-cooled information handling system, in accordance with embodiments of the present disclosure. According to some embodiments, method 300 may begin at step 302. As noted above, teachings of the present disclosure may be implemented in a variety of configurations of information handling system 102. As such, the preferred initialization point for method 300 and the order of the steps comprising method 300 may depend on the implementation chosen.

At step 302, management controller 112 may receive speed signal SPEED from pump speed sensor 138. At step 304, management controller 112 may compare the speed indicated by speed signal SPEED to a threshold pump speed. If the monitored pump speed is greater than the threshold pump speed, which may be indicative that a particular volume of liquid cooling has been depleted from liquid cooling system 118, method 300 may proceed to step 306. Otherwise, method 300 may proceed again to step 302, and repeat execution of steps 302 and 304 until such time as the monitored pump speed is greater than the threshold pump speed.

At step 306, responsive to the monitored pump speed exceeding the threshold pump speed, management controller 112 may determine that a significant volume of liquid coolant has been depleted from liquid cooling system 118, and may take one or more remedial actions in response to such depletion. For example, in some embodiments, a remedial action may include communicating an audio and/or visual alert to a user or administrator of information handling system 102. In these and other embodiments, a remedial action may include throttling device 116 and/or other components of information handling system 102 in order to minimize generation of heat. In these and other embodiments, such remedial action may include a forced shutdown of information handling system 102.

Although FIG. 3 discloses a particular number of steps to be taken with respect to method 300, method 300 may be executed with greater or fewer steps than those depicted in FIG. 3. In addition, although FIG. 3 discloses a certain order of steps to be taken with respect to method 300, the steps comprising method 300 may be completed in any suitable order.

Method 300 may be implemented using a host information handling system 102 and/or any other system operable to implement method 300. In certain embodiments, method 300 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described above, the principles of the present disclosure may be implemented using any number of techniques, whether currently known or not. The present disclosure should in no way be limited to the exemplary implementations and techniques illustrated in the figures and described above.

Unless otherwise specifically noted, articles depicted in the figures are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. An information handling system comprising:
an information handling resource;
a liquid cooling system for providing cooling of the information handling resource, the liquid cooling system comprising:
a pump configured to drive flow of a liquid coolant through the liquid cooling system;
a pump speed sensor configured to generate a pump speed signal indicative of a speed associated with the pump; and
a processing device configured to:
receive the pump speed signal;
determine whether the speed exceeds a threshold pump speed; and
if the speed exceeds the threshold pump speed, take one or more remedial actions.

2. The information handling system of claim 1, wherein the liquid cooling system provides active cooling of the information handling resource.

3. The information handling system of claim 1, further comprising an air mover configured to drive an airflow of air proximate to a radiator of the liquid cooling system such that the liquid cooling system together with the air mover provides liquid-assisted air cooling of the information handling resource.

4. The information handling system of claim 1, wherein the one or more remedial actions comprise one or more of an audio alert, a visual alert, throttling of the information handling resource, and shutdown of one or more components of the information handling system.

5. A method comprising, in an information handling system having an information handling resource and a liquid cooling system for providing cooling of the information handling resource:
receiving a pump speed signal indicative of speed associated with a pump configured to drive flow of a liquid coolant through the liquid cooling system;
determining whether the speed exceeds a threshold pump speed; and
if the speed exceeds the threshold pump speed, taking one or more remedial actions.

6. The method of claim 5, wherein the liquid cooling system provides active cooling of the information handling resource.

7. The method of claim 5, wherein the information handling system further has an air mover configured to drive an airflow of air proximate to a radiator of the liquid cooling system such that the liquid cooling system together with the air mover provide liquid-assisted air cooling of the information handling resource.

8. The method of claim 5, wherein the one or more remedial actions comprise one or more of an audio alert, a visual alert, throttling of the information handling resource, and shutdown of one or more components of the information handling system.

9. A system for detecting depletion of a liquid from a liquid system, the system comprising:
a pump speed sensor configured to generate a pump speed signal indicative of a speed associated with a pump for driving flow of liquid through the liquid system; and
a processing device configured to:
receive the pump speed signal;
determine whether the speed exceeds a threshold pump speed; and
if the speed exceeds the threshold pump speed, take one or more remedial actions.

10. The system of claim 9, wherein the one or more remedial actions comprise one or more of an audio alert, a visual alert, throttling of an electronic component cooled by the liquid system, and shutdown of one or more components of an electronic system cooled by the liquid system.

11. An article of manufacture comprising:
a non-transitory computer-readable medium; and
computer-executable instructions carried on the computer-readable medium, the instructions readable by a processor, the instructions, when read and executed, for causing the processor to, in an information handling system having an information handling resource and a liquid cooling system for providing cooling of the information handling resource:
receive a pump speed signal indicative of speed associated with a pump configured to drive flow of a liquid coolant through the liquid cooling system;
determine whether the speed exceeds a threshold pump speed; and
if the speed exceeds the threshold pump speed, take one or more remedial actions.

12. The article of manufacture of claim 11, wherein the liquid cooling system provides active cooling of the information handling resource.

13. The article of manufacture of claim 11, wherein the information handling system further has an air mover configured to drive an airflow of air proximate to a radiator of the liquid cooling system such that the liquid cooling system together with the air mover provide liquid-assisted air cooling of the information handling resource.

14. The article of manufacture of claim 11, wherein the one or more remedial actions comprise one or more of an audio alert, a visual alert, throttling of the information handling resource, and shutdown of one or more components of the information handling system.
